(19) United States
(12) Patent Application Publication
(10) Pub. No.: US 2010/0102430 A1
(43) Pub. Date: Apr. 29, 2010

(54) SEMICONDUCTOR MULTI-CHIP PACKAGE

(75) Inventors: Tae Soo LEE, Suwon (KR); Yun Hwi Park, Yongin (KR); Yun Hee Cho, Hwaseong (KR)

Correspondence Address: MCDERMOTT WILL & EMERY LLP, 18191 VON KARMAN AVE., SUITE 500, IRVINE, CA, 92612-7108, US

(73) Assignee: SAMSUNG ELECTRO-MECHANICS CO., LTD., Suwon (KR)

(21) Appl. No.: 12/476,221

(22) Filed: Jun. 1, 2009

(30) Foreign Application Priority Data
Oct. 23, 2008 (KR) 10-2008-0104464

(51) Int. Cl. H01L 23/488; H01L 23/48

(52) U.S. Cl. 257/690; 257/725; 257/E23.141; 257/E23.023

(57) ABSTRACT

A semiconductor multichip package includes a substrate having a top surface on which a bonding pad is formed, and a bottom surface opposing the top surface, on which an external connection terminal electrically connected with the bonding pad is formed, a first semiconductor chip mounted on a region of the top surface of the substrate excluding the bonding pad, a ceramic spacer disposed on a top surface of the first semiconductor chip and including a passive device therein, and at least one second semiconductor chip disposed on a top surface of the ceramic spacer. The ceramic spacer includes an interlayer circuit for an electrical connection between the first and second semiconductor chips, and the passive device is electrically connected to at least one of the first and second semiconductor chips. Accordingly, a package with a more compact structure can be realized.

### CROSS-REFERENCE TO RELATED APPLICATIONS

This application claims the priority of Korean Patent Application No. 2008-0104464 filed on Oct. 23, 2008, in the Korean Intellectual Property Office, the disclosure of which is incorporated herein by reference.

### BACKGROUND OF THE INVENTION

1. Field of the Invention

The present invention relates to a semiconductor multichip package, and more particularly, to a semiconductor multichip package capable of mounting a plurality of semiconductor chips in a single package for the miniaturization of the package by reducing the number of components mounted on a substrate and thus reducing the size of the substrate.

2. Description of the Related Art

The recent advancements in the semiconductor industry have accelerated the development of smaller and lighter electronic devices with more functions. In this regard, packaging of semiconductor chips is performed to make electronic devices smaller, slimmer and more functional and improve the performance and quality of electronic devices rather than to simply protect or mount the semiconductor chip in the electronic device. A technique for incorporating like or different semiconductor chips into a single unit package is called multichip packaging.

Compared to the case of implementing each semiconductor chip in one individual package, multichip packaging is desirable in terms of the size, weight and mounting area of the package. Particularly, multichip packaging is in common use in order to realize high-integration, high performance integrated circuits as portable computers are miniaturized.

In the multichip packaging technique for incorporating a plurality of semiconductor devices, such as chips or dies, into one package, the semiconductor devices may be stacked on top of each other or disposed parallel to one another. As for parallel disposition, two semiconductor chips are arranged on the plane, which makes it difficult to achieve a reduction in the size of a package. For this reason, parallel disposition is not considered in the present invention as it is unsuitable for the miniaturization of the package.

As for the stacking of the semiconductor devices on top of each other, a multichip package includes a first semiconductor chip mounted on a substrate, a second semiconductor chip disposed on the first semiconductor chip having a predetermined distance therebetween, and a spacer disposed between the first and second semiconductor chips, having a predetermined height to maintain the distance between the first and second semiconductor chips. The first and second semiconductor chips are wire-bonded with bonding pads on the substrate by use of bonding wires, thereby forming an electrical connection therebetween.

Passive devices such as a resistor, a capacitor and a coil are also mounted on the substrate. The spacer serves to ensure a space, which has no function besides a bonding function between the semiconductor chips. Thus, the related art multichip package requires a space for mounting the passive devices on the substrate, causing limitations in reducing the package in size.

### SUMMARY OF THE INVENTION

An aspect of the present invention provides a package which can have a small size by interposing a ceramic spacer, which includes therein passive devices, between chips.

According to an aspect of the present invention, there is provided a semiconductor multichip package including: a substrate having a top surface on which a bonding pad is formed, and a bottom surface opposing the top surface, on which an external connection terminal electrically connected with the bonding pad is formed; a first semiconductor chip mounted on a region of the top surface of the substrate excluding the bonding pad; a ceramic spacer disposed on a top surface of the first semiconductor chip and including a passive device therein; and at least one second semiconductor chip disposed on a top surface of the ceramic spacer. The ceramic spacer includes an interlayer circuit for an electrical connection between the first and second semiconductor chips, and the passive device is electrically connected to at least one of the first and second semiconductor chips.

The semiconductor multichip package may further include a first bonding wire electrically connecting the first semiconductor chip to the bonding pad.

The ceramic spacer may have a height greater than the height of the first bonding wire above the top surface of the first semiconductor chip.

The ceramic spacer may be a low temperature co-fired ceramic (LTCC) substrate. The passive device may be at least one of a resistor, an inductor, a capacitor, a filter, a balun, a coupler, a decoupling capacitor and an electrostatic discharge device.

The second semiconductor chip may include a throughhole for an electrical connection with the ceramic spacer.

The semiconductor multichip package may further include a plurality of bumps formed on a bottom surface of the first semiconductor chip and electrically connected to the first semiconductor chip. The first semiconductor chip may include a through hole electrically connected to each bump. The semiconductor multichip package may further include an adhesive layer filling a gap between the plurality of bumps to seal the space between the first semiconductor chip and the substrate.

The semiconductor multichip package may further include a second bonding wire electrically connecting the second semiconductor chip to the bonding pad. The substrate may be a ceramic substrate. A circuit pattern may be printed on the top surface of the substrate. The substrate may include a mold part encompassing the first and second semiconductor chips.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view of a semiconductor multichip package according to an exemplary embodiment of the present invention;

FIG. 2 is a plan view of the semiconductor multichip package of FIG. 1; and

FIG. 3 is a cross-sectional view of a semiconductor multichip package according to another exemplary embodiment of the present invention.

### DETAILED DESCRIPTION OF THE PREFERRED EMBODIMENT

Exemplary embodiments of the present invention will now be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. In the figures, the dimensions and shapes of the elements are exaggerated for clarity of illustration.

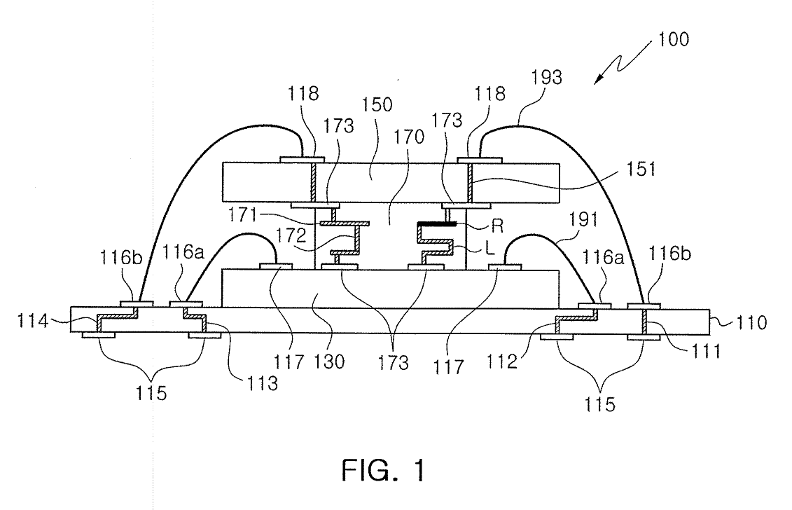

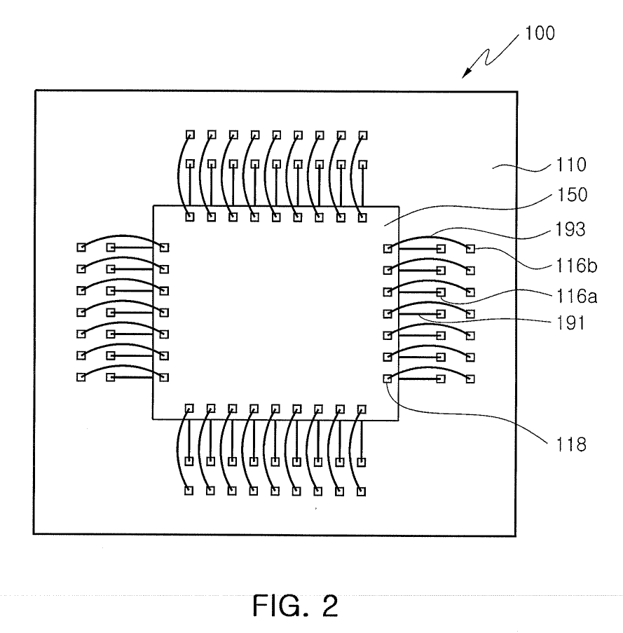

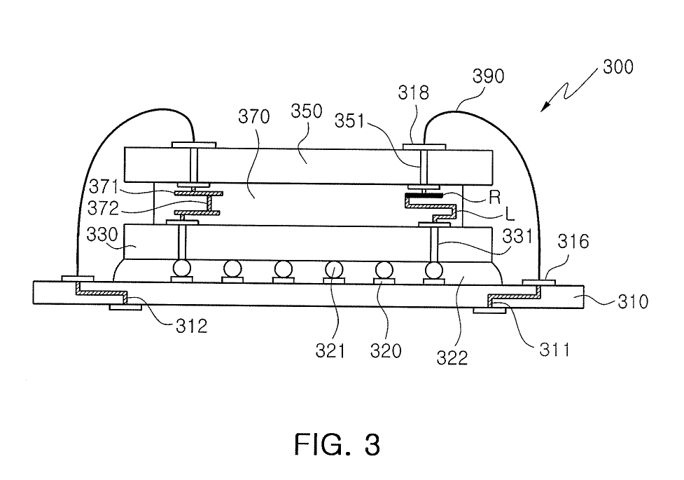

FIG. 1 is a cross-sectional view of a semiconductor multichip package according to an exemplary embodiment of the present invention. FIG. 2 is a plan view of the semiconductor multichip package of FIG. 1. FIG. 3 is a cross-sectional view of a semiconductor multichip package according to another exemplary embodiment of the present invention.

A semiconductor multichip package includes: a substrate having a top surface on which a bonding pad is formed, and a bottom surface opposing the top surface, on which an external connection terminal electrically connected with the bonding pad is formed; a first semiconductor chip mounted on a region of the top surface of the substrate excluding the bonding pad; a ceramic spacer disposed on a top surface of the first semiconductor chip and including a passive device therein; and at least one second semiconductor chip disposed on a top surface of the ceramic spacer. The ceramic spacer includes an interlayer circuit for an electrical connection between the first and second semiconductor chips, and the passive device is electrically connected to at least one of the first and second semiconductor chips.

The semiconductor multichip package may further include a first bonding wire electrically connecting the first semiconductor chip to the bonding pad.

The ceramic spacer may have a height greater than the height of the first bonding wire above the top surface of the first semiconductor chip.

The ceramic spacer may be a low temperature co-fired ceramic (LTCC) substrate. The passive device may be at least one of a resistor, an inductor, a capacitor, a filter, a balun, a coupler, a decoupling capacitor and an electrostatic discharge device.

The second semiconductor chip may include a throughhole for an electrical connection with the ceramic spacer.

The semiconductor multichip package may further include a plurality of bumps formed on a bottom surface of the first semiconductor chip and electrically connected to the first semiconductor chip. The first semiconductor chip may include a through hole electrically connected to each bump. The semiconductor multichip package may further include an adhesive layer filling a gap between the plurality of bumps to seal the space between the first semiconductor chip and the substrate.

The semiconductor multichip package may further include a second bonding wire electrically connecting the second semiconductor chip to the bonding pad. The substrate may be a ceramic substrate. A circuit pattern may be printed on the top surface of the substrate. The substrate may include a mold part encompassing the first and second semiconductor chips.

FIG. 1 is a cross-sectional view of a semiconductor multichip package according to an exemplary embodiment of the present invention. As shown in FIG. 1, a semiconductor multichip package 100, according to this embodiment, is configured to reduce the number of components mounted on a substrate and reduce the substrate in size to thereby miniaturize end products. The semiconductor multichip package 100 includes a substrate 110, first and second semiconductor chips 130 and 150, and a ceramic spacer 170 including a passive device.

The substrate 110 is a ceramic substrate formed by stacking one or more ceramic layers and including internal electrode patterns 111, 112, 113, 114 therein. Various circuits are formed on the top surface of the ceramic substrate by pattern printing, and a plurality of bonding pads 116a and 116b for wire bonding are also formed on the top surface thereof. A plurality of mounting components (not shown) may be mounted, corresponding to the circuits formed through pattern printing.

A plurality of external connection terminals 115 are formed on the bottom surface of the substrate 110. A solder ball (not shown) is formed at each of the external connection terminals 115 for the electrical connection with a main substrate. The semiconductor multichip package 100 is mounted on the main substrate by use of a solder ball.

As for the substrate 110, passive devices for realizing given circuits, such as a resistor (R), an inductor (L), a capacitor (C), a filter, a balun and a coupler, are provided on a plurality of green sheets made based on a glass-ceramic material by screen printing and photo-patterning using Ag, Cu or the like having a high level of electrical conductivity. Also, after the green sheets on which the given circuits are realized are stacked, the ceramic and the metal conductors are co-fired at a temperature of 1000° C. or lower. Thus, the substrate 110 is provided as a low temperature co-fired ceramic (LTCC) substrate.

Accordingly, the passive devices such as the capacitor, the resistor and the inductor, mounted on the substrate 110 in the related art, may be mounted in the form of patterns inside the substrate 110.

The first semiconductor chip 130 is a chip component mounted on the top surface of the substrate 110 and electrically connected with the circuits, which are formed on the top surface of the substrate 110 by pattern printing. The first semiconductor chip 130 is bonded to the substrate 110 through a plurality of first bonding wires 191 and thus is electrically connected to the substrate 110. The first semiconductor chip 130 is adhered to the substrate 110 by an insulating adhesive (not shown). However, the first semiconductor chip 130 is not limited to the description. For example, ball pads (not shown) may be formed on the bottom surface of the first semiconductor chip 130, and a plurality of solder balls (not shown) may be provided on the ball pads, so that the first semiconductor chip 130 can be mounted on the top surface of the substrate 110 by flip-chip bonding.

The first bonding wire 191 is a wire member having one end bonded with a first chip pad 117 on the top surface of the first semiconductor chip 130, and the other end bonded with a first bonding pad 116a formed on the substrate 110.

The second semiconductor chip 150 is at least one chip component disposed directly above the first semiconductor chip 130 with a predetermined distance therebetween. The second semiconductor chip 150 is not directly connected to the substrate 110, and is stacked on the first semiconductor chip 130 with the ceramic spacer 170 interposed therebetween. Here, the ceramic spacer 170 includes conductive lines including via holes 171 and conductive patterns 172 in its body. The second semiconductor chip 150 is electrically connected to the internal conductive lines and the passive devices of the ceramic spacer 170 through the through holes 151 formed in the second semiconductor chip 150 by a physical method such as punching. The through holes 151 are filled with conductive paste.

The second semiconductor chip 150 is connected to the substrate 110 via the second bonding wire 193. In detail, the second bonding wire 193 has one end bonded with a second chip pad 118 on the top surface of the second semiconductor chip 150, and the other end bonded with a second bonding pad 116b on the top surface of the substrate 110. The first and second semiconductor chips 130 and 150 may each be configured as a memory chip, such as a static random access memory (SRAM) or a dynamic random access memory (DRAM), a digital integrated circuit (IC) chip, a radio-frequency (RF) IC chip, or a base band chip.

The ceramic spacer 170 is a distance maintaining member having the top end and the bottom end connected to the bottom surface of the second semiconductor chip 150 and the top surface of the first semiconductor chip 130 respectively in order to maintain the distance between the first and second semiconductor chips 130 and 150. The ceramic spacer 170 has a greater thickness than the maximum extent of the first bonding wire 191 above the top surface of the first semiconductor chip. The ceramic spacer 170 includes interlayer circuits 171 and 172 to electrically connect the first semiconductor chip 130 with the second semiconductor chip 150.

The ceramic spacer 170 is provided as an LTCC substrate including at least one passive device such as an R, an L, a C, a filter, a balun and a coupler and is disposed between the first and second semiconductor chips 130 and 150 to be electrically connected to the second semiconductor chip 150 or the first semiconductor chip 130.

In this case, additional passive devices required according to the operational type of the second semiconductor chip 150, such as an R, an L, a C, a filter, a balun, a coupler, a decoupling capacitor or an electrostatic discharge (ESD) device, can be mounted directly within the ceramic spacer 170 without being mounted on the substrate 110. Accordingly, the number of components mounted on the substrate 110 can be reduced.

The ceramic spacer 130 is adhered to the top surface of the first semiconductor chip 130 and the bottom surface of the second semiconductor chip 150 by use of an insulating adhesive (not shown).

A mold part (not shown) is formed of a mold resin, such as an epoxy molding compound, over the substrate 110 to encompass the first semiconductor chip 130, the second semiconductor chip 150 and the first and second bonding wires 191 and 193, thereby protecting them from external physical damage and corrosion. In this manner, one package form is constructed.

FIG. 2 is a plan view of the semiconductor multichip package of FIG. 1. The same reference numerals are used for the same members as in FIG. 1. Thus, a detailed description thereof will be omitted.

In the semiconductor multichip package as shown in FIG. 2, the first bonding pad 116a of the substrate 110 is connected to the first chip pad 117 of the first semiconductor chip 130 through the first bonding wire 191. Also, the second bonding pad 116b of the substrate 110 is connected to the second chip pad 118 of the second semiconductor chip 150 through the second bonding wire 193.

FIG. 3 is a cross-sectional view of a semiconductor multichip package according to another exemplary embodiment of the present invention. As shown in FIG. 3, a semiconductor multichip package 300 according to this embodiment includes a substrate 310, a first semiconductor chip 330 mounted on the substrate 310, a second semiconductor chip 350 disposed directly above the first semiconductor chip 330, and a ceramic spacer 370 disposed between the first semiconductor chip 330 and the second semiconductor chip 350 and electrically connecting the first and second semiconductor chips 330 and 350. Here, the semiconductor chips are mounted on the substrate and the spacer is mounted between the semiconductor chips in the same manner as described with reference to FIG. 1. Therefore, a detailed description thereof will be omitted.

The substrate 310 is a ceramic substrate formed of a stack of one or more ceramic layers, and including an internal electrode pattern 312 therein. Various circuits are formed by pattern printing on the top surface of the substrate 310, and a plurality of bonding pads 316 for wire bonding are also formed thereon.

The first semiconductor chip 330 and the second semiconductor chip 350 are stacked vertically to face each other with the ceramic spacer 370 interposed therebetween. The first semiconductor chip 330 has a through hole 331 therein. The first semiconductor chip 330 is bonded with a bonding pad 320 through a bump 321 formed on the bottom surface of the first semiconductor chip 330 corresponding to the through hole 331, thereby forming an electrical connection with the substrate 310. The through hole 331 is filled with conductive paste. The first semiconductor chip 330 is electrically connected with passive devices inside the ceramic spacer 370 through the through hole 331. Here, the passive devices may include an R, an L, a C, a filter, a balun and a coupler.

The second semiconductor chip 350 is electrically connected to the substrate 310 through a chip pad 318 and a bonding wire 390. Like the first semiconductor chip 330, the second semiconductor chip 350 is also electrically connected to the passive device, such as an R, an L, a C, a filter, a balun and a coupler, inside the ceramic spacer 370, through a through hole 351.

In the semiconductor multichip package 300, an adhesive layer 322 seals the space between the first semiconductor chip 330 and the substrate 310. The adhesive layer 322 is obtained by filling the gaps between the bumps 321, which are connected to the bottom surface of the first semiconductor chip 330, that is, on the top surface of the substrate 310, with an underfilling material, and then hardening the underfilling material.

The ceramic spacer 370 is an LTCC substrate that includes therein passive devices such as an R, an L, a C, a filter, a balun and a coupler, as well as via holes and conductive patterns for the electrical connection between the first and second semiconductor chips 330 and 350.

Accordingly, in the semiconductor multichip packages 100 and 300 according to the embodiments of the present invention, the first and second semiconductor chips are stacked vertically with the ceramic spacer interposed therebetween, which can include passive devices therein. Thus, additional passive devices such as an R, an L, a C, a filter, a balun, a decoupling capacitor or ESD device, which are used according to the design, may be mounted directly inside the ceramic spacer without being mounted on the substrate 310. Consequently, the number of components additionally mounted on the substrate is reduced, thereby making the entire package slimmer and smaller.

Also, in the semiconductor multichip packages 100 and 300 according to the present invention, the ceramic spacer including the passive devices allows a reduction in the distance between the chip and the passive devices, thus improving module characteristics. Such a ceramic spacer also allows a reduction in the size of the substrate, contributing to saving on overall manufacturing costs.

The semiconductor multichip package according to the present invention employs a ceramic spacer including therein passive devices and interposed between semiconductor chips, so that a reduction in the size of the entire substrate can be achieved, realizing a compact package. The semiconductor multichip package employing the ceramic spacer including passive devices is applicable to both a package type structure including a stack of multiple chips connected through wire-bonding, and a hybrid structure of flip-chip bonding and wire-bonding.

Also, the semiconductor multichip package according to the present invention uses a ceramic spacer including passive devices between semiconductor chips, so that the path between the passive devices and the active devices, that is, the semiconductor chips, can be reduced, thereby improving module characteristics.

While the present invention has been shown and described in connection with the exemplary embodiments, it will be apparent to those skilled in the art that modifications and variations can be made without departing from the spirit and scope of the invention as defined by the appended claims.

What is claimed is:

1. A semiconductor multichip package comprising:
a substrate having a top surface on which a bonding pad is formed, and a bottom surface opposing the top surface, on which an external connection terminal electrically connected with the bonding pad is formed;
a first semiconductor chip mounted on a region of the top surface of the substrate excluding the bonding pad;
a ceramic spacer disposed on a top surface of the first semiconductor chip and including a passive device therein; and
at least one second semiconductor chip disposed on a top surface of the ceramic spacer,
wherein the ceramic spacer includes an interlayer circuit for an electrical connection between the first and second semiconductor chips, and the passive device is electrically connected to at least one of the first and second semiconductor chips.

2. The semiconductor multichip package of claim 1, further comprising a first bonding wire electrically connecting the first semiconductor chip to the bonding pad.

3. The semiconductor multichip package of claim 2, wherein the ceramic spacer has a height greater than the height of the first bonding wire above the top surface of the first semiconductor chip.

4. The semiconductor multichip package of claim 1, wherein the ceramic spacer is a low temperature co-fired ceramic (LTCC) substrate.

5. The semiconductor multichip package of claim 4, wherein the passive device is at least one of a resistor, an inductor, a capacitor, a filter, a balun, a coupler, a decoupling capacitor and an electrostatic discharge device.

6. The semiconductor multichip package of claim 1, wherein the second semiconductor chip comprises a through hole for an electrical connection with the ceramic spacer.

7. The semiconductor multichip package of claim 1, further comprising a plurality of bumps formed on a bottom surface of the first semiconductor chip and electrically connected to the first semiconductor chip.

8. The semiconductor multichip package of claim 7, wherein the first semiconductor chip comprises a through hole electrically connected to each bump.

9. The semiconductor multichip package of claim 7, further comprising an adhesive layer filling a gap between the plurality of bumps to seal the space between the first semiconductor chip and the substrate.

10. The semiconductor multichip package of claim 1, further comprising a second bonding wire electrically connecting the second semiconductor chip to the bonding pad.

11. The semiconductor multichip package of claim 1, wherein the substrate is a ceramic substrate.

12. The semiconductor multichip package of claim 1, wherein a circuit pattern is printed on the top surface of the substrate.

13. The semiconductor multichip package of claim 1, wherein the substrate comprises a mold part encompassing the first and second semiconductor chips.
